(19) United States
(12) Patent Application Publication
(10) Pub. No.: US 2012/0161750 A1
(43) Pub. Date: Jun. 28, 2012

(54) ELECTRONIC WATT-HOUR METER AND METHOD OF CALCULATING WATT-HOURS

(75) Inventor: Yo Sub MOON, Hwaseung (KR)

(73) Assignee: SAMSUNG ELECTRO-MECHANICS CO., LTD., Suwon (KR)

(21) Appl. No.: 13/038,670

(22) Filed: Mar. 2, 2011

(30) Foreign Application Priority Data
Dec. 22, 2010 (KR) 10-2010-0132292

(51) Int. Cl. G01R 21/06

(52) U.S. Cl. 324/116

(57) ABSTRACT

Disclosed is an electronic watt-hour meter including: a plurality of sigma-delta modulators converting a plurality of analog detection currents, acquired by detecting currents flowing through a plurality of power lines having different phases, and a plurality of analog detection voltages, acquired by detecting voltages applied to the plurality of power lines, into respective bitstreams; a first register storing the bitstreams of the plurality of detection currents; a second register storing the bitstreams of the plurality of detection voltages; a register controller controlling the first register and the second register to sequentially output the bitstreams of the plurality of detection currents and the bitstreams of the plurality of detection voltages while simultaneously outputting bitstreams of detection currents and bitstreams of detection voltages detected in the same power line; a first decimation filter converting the bitstreams of the plurality of detection currents sequentially outputted from the first register into digital values; and a second decimation filter converting the bitstreams of the plurality of detection voltages sequentially outputted from the second register into digital values.

### CROSS-REFERENCE TO RELATED APPLICATIONS

This application claims the priority of Korean Patent Application No. 10-2010-0132292 filed on Dec. 22, 2010, in the Korean Intellectual Property Office, the disclosure of which is incorporated herein by reference.

### BACKGROUND OF THE INVENTION

1. Field of the Invention

The present invention relates to an electronic watt-hour meter, and more particularly, to an electronic watt-hour meter and a method of calculating watt-hours capable of reducing the size thereof and improving calculation accuracy.

2. Description of the Related Art

In recent years, attention paid to the idea of a so-called “smart grid” has increased. The concept of a smart grid is an intelligent power distribution network system improving efficiency through interactions between suppliers and consumers by combining telecommunications technology with the processes of the transportation, production, and consumption of electricity.

In a smart grid system, a power supplier determines a user' s expected power consumption through an IT medium in real time to provide against power shortage. In contrast, a user may determine his or her power consumption and related fees from a power supplier in real time to determine his or her power use patterns.

Ease of information exchange through a telecommunications network between the power supplier and the user is required for the implementation of the smart grid. Further, technology able to accurately calculate watt-hours and convert the calculated power consumption into digital information, as well as communications technology able to transmit the converted digital information is required.

Meanwhile, an inductive watt-hour meter comprises most known watt-hour meters, and power consumption is displayed through a rotary analog instrument panel. Since it is difficult for an analogue type watt-hour calculator to convert watt-hours into digital information, the transmission of data related thereto through telecommunications networks is difficult. Accordingly, watt-hours are converted into digital information by a semiconductor circuit element, such as an analog-digital converter, in an electronic watt-hour meter which has been spread in recent years, and the converted information may be transmitted through a communication module.

However, a sigma-delta analog-digital converter used to convert detected analog current or voltage into direct current (DC) occupies large amount of space within such an electronic watt-hour meter. In particular, since more sigma-delta analog-digital converters should be used to detect watt-hours for a power line having three or more plural phases, the miniaturization of an electronic watt-hour meter is very difficult.

Further, there is known technology which allows plural analog detection currents or detection voltages to share a single sigma-delta analog-digital converter by using an analog multiplexer (MUX) or a demultiplexer (DEMUX). However, since components for analog calculation are many and digital conversion is sequentially performed in the technology, a phase difference is generated between a current and a voltage detected on the same power line, ad a result, calculation accuracy is deteriorated and an additional circuit for compensating for the phase difference is required.

### SUMMARY OF THE INVENTION

An aspect of the present invention provides an electronic watt-hour meter and a method of calculating watt-hours, capable of reducing the size thereof and accurately calculating watt-hours by digitalizing circuit components.

According to an aspect of the present invention, there is provided an electronic watt-hour meter including: a plurality of sigma-delta modulators converting a plurality of analog detection currents, acquired by detecting currents flowing through a plurality of power lines having different phases, and a plurality of analog detection voltages, acquired by detecting voltages applied to the plurality of power lines, into respective bitstreams; a first register storing the bitstreams of the plurality of detection currents; a second register storing the bitstreams of the plurality of detection voltages; a register controller controlling the first register and the second register to sequentially output the bitstreams of the plurality of detection currents and the bitstreams of the plurality of detection voltages, respectively, while simultaneously outputting bitstreams of detection currents and bitstreams of detection voltages detected in the same power line; a first decimation filter converting the bitstreams of the plurality of detection currents sequentially outputted from the first register into digital values; and a second decimation filter converting the bitstreams of the plurality of detection voltages sequentially outputted from the second register into digital values.

The electronic watt-hour meter may further include third and fourth registers storing the digital values of the plurality of detection currents outputted from the first decimation filter and the plurality of detection voltages outputted from the second decimation filter, respectively, according to each of the plurality of power lines. The register controller may control the third register and the fourth register to distinguish the power lines, through which the digital values are sequentially inputted into the third register and the fourth register, and store the digital values in different addresses.

The register controller may provide a clock controlling a writing operation and a clock controlling a reading operation to the first register and the second register, and a frequency of the clock controlling the reading operation may be n times (n is the number of the plurality of power lines having different phases) more than that of the clock controlling the writing operation.

The electronic watt-hour meter may further include a plurality of additional sigma-delta modulators receiving at least one piece of analog information including a detection leakage current acquired by detecting a current flowing through a neutral power line, a detection temperature acquired by detecting an ambient temperature, and an analog power voltage, and converting values corresponding thereto into bitstreams; a fifth register storing the plurality of bitstreams converted by the plurality of additional sigma-delta modulators and sequentially outputting the plurality of bitstreams by a control of the register controller; and a third decimation filter converting the bitstreams sequentially outputted from the fifth register into digital values.

The electronic watt-hour meter may further include a sixth register storing the digital values converted by the third decimation filter according to types of the analog information.

According to another aspect of the present invention, there is provided a method of calculating watt-hour, the method including: converting a plurality of analog detection currents, acquired by detecting currents flowing through a plurality of power lines having different phases, and a plurality of analog detection voltages, acquired by detecting voltages applied to the plurality of power lines, into respective bitstreams through sigma-delta modulation; storing the bitstreams of the plurality of detection currents in a first register; storing the bitstreams of the plurality of detection voltages in a second register; sequentially outputting, by the first register and the second register, the. bitstreams of the plurality of detection currents and the bitstreams of the plurality of detection voltages while simultaneously outputting bitstreams of detection currents and bitstreams of detection voltages detected in the same power line; and converting the bitstreams of the plurality of detection currents, sequentially outputted from the first register, into digital values and converting the bitstreams of the plurality of detection voltages, sequentially outputted from the second register, into digital values.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram of an electronic watt-hour meter according to an exemplary embodiment of the present invention;

FIG. 2 is a flowchart showing a method of calculating watt-hours implemented by an electronic watt-hour meter according to an exemplary embodiment of the present invention; and

FIG. 3 is a timing diagram showing a register control clock and a register operation of an electronic watt-hour meter according to an exemplary embodiment of the present invention.

### DETAILED DESCRIPTION OF THE PREFERRED EMBODIMENT

Hereinafter, exemplary embodiments of the present invention will be described in detail with reference to the accompanying drawings.

However, the exemplary embodiments of the present invention may be modified in various forms and the scope of the present invention is not limited to the exemplary embodiments described below. Exemplary embodiments of the present invention are provided so that those skilled in the art may more completely understand the present invention. Accordingly, the shapes and sizes of elements in the drawings maybe exaggerated for clarity and like reference numerals refer to like elements throughout the drawings.

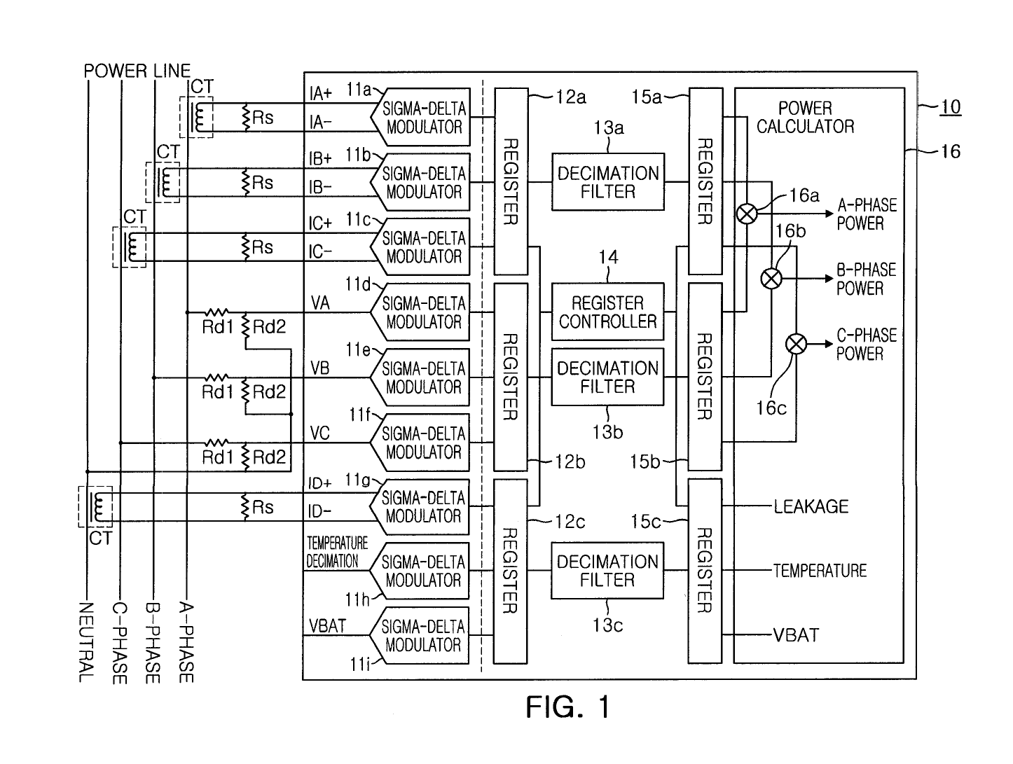

FIG. 1 is a block diagram of an electronic watt-hour meter according to an exemplary embodiment of the present invention.

Referring to FIG. 1, an electronic watt-hour meter 10 according to an exemplary embodiment of the present invention may include a plurality of sigma-delta modulators 11a to 11i, a plurality of registers 12a to 12c storing outputs of the sigma-delta modulators 11a to 11i, and a register controller 14 controlling the plurality of registers 12a to 12c, a plurality of decimation filters 13a to 13c converting the outputs of the plurality of registers 12a to 12c into digital signals, a plurality of registers 15a to 15c storing outputs of the plurality of decimation filters 13a to 13c, and a power calculator 16 calculating watt-hours by using outputs of the plurality of registers 15a to 15c.

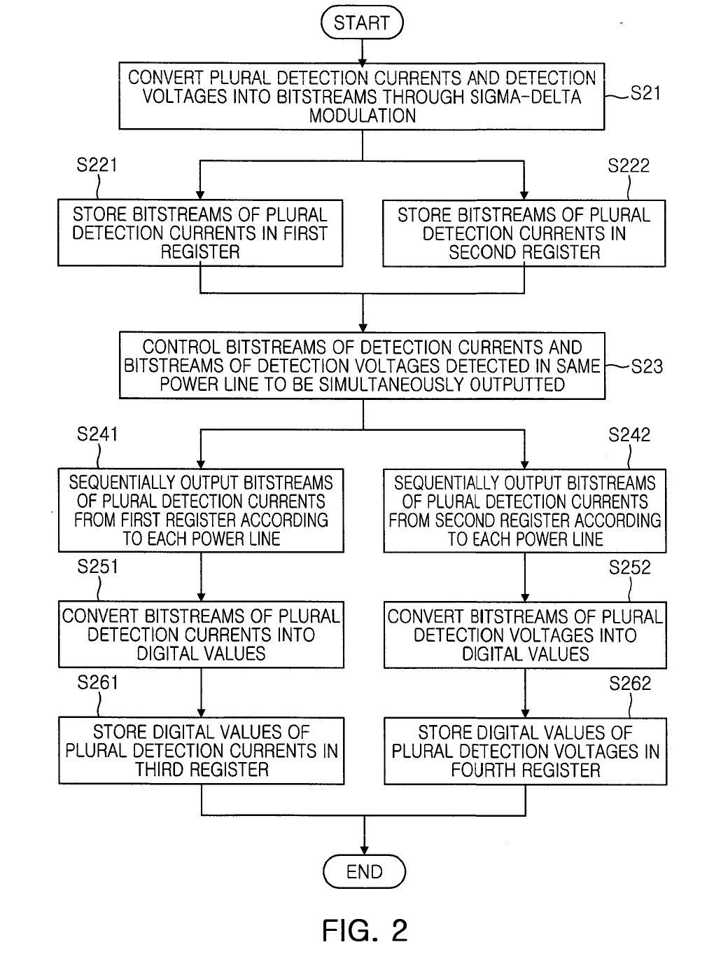

FIG. 2 is a flowchart showing a method of calculating watt-hours implemented by an electronic watt-hour meter according to an exemplary embodiment of the present invention.

Hereinafter, referring to FIGS. land 2, the operations of individual elements according to a sequence of calculating watt-hours by an electronic watt-hour meter according to an exemplary embodiment of the present invention will be described in detail.

First, an electronic watt-hour meter according to an exemplary embodiment of the present invention converts analog detection currents and detection voltages, detected from a plurality of power lines having different phases, into bitstreams by using a sigma-delta modulation technique (S21).

The electronic watt-hour meter 10 receives analog detection voltage and detection current detected from each power line and calculates watt-hours by using the inputted detection voltage and detection current. As the power line, a single-phase power line, mainly provided to a home, and a 3-phase (A, B, and C phases) power line, provided to a factory or a business that consumes a lot of watt-hours, are primarily used. When a plurality of power lines having different phases such as the 3-phase power line are used, a current detector and a voltage detector may be used to detect a current flowing through each of the plurality of power lines and a voltage applied thereto.

A current transformer (CT) may be used to detect currents flowing through the plurality of power lines having different phases. For example, in the current transformer (CT), a winding ratio may be adjusted so as to allow the detected current to have a magnitude reduced to one thousandth of the magnitude of a current actually flowing through the power line.

Further, two voltage dividing resistors Rd1 and Rd2 may be used to detect the voltages applied to the plurality of power lines having different phases. The two voltage dividing resistors Rd1 and Rd2 may dividedly output a voltage difference between each of the A to C-phase power lines and a neutral power line. For example, resistance values of two voltage dividing resistors Rd1 and Rd2 may be adjusted to have a magnitude reduced to one thousandth of the magnitude of the voltage actually applied to the power line.

The detection currents, detected by the current transformer (CT), or the detection voltages, detected by the voltage dividing resistors Rd1 and Rd2, are in the form of analog signals. The analog detection current and detection voltage are inputted into the electronic watt-hour meter 10, converted into digital bitstreams, and used to calculate watt-hours.

The plurality of sigma-delta modulators 11a to 11f included in the electronic watt-hour meter 10 according to the exemplary embodiment of the present invention receive the plurality of analog detection currents and the plurality of analog detection voltages, which are detected from the plurality of power lines, and sigma-delta modulate the plurality of analog detection currents and detection voltages and output digital bitstreams.

Among general analog-digital converters, a sigma-delta analog-digital converter is primarily adopted in an electronic watt-hour meter. The sigma-delta analog-digital converter may be implemented by a sigma-delta modulator and a decimation filter. According to the exemplary embodiment of the present invention, the sigma-delta modulator and the decimation filter of a general sigma-delta analog-digital converter are separated from each other and output signals of a plurality of sigma-delta modulators may be processed by using a single decimation filter.

The plurality of sigma-delta modulators 11a to 11f oversample the received analog signal according to a predetermined oversampling frequency, integrate a difference between the oversampled analog signal and a feedback signal, and quantize the integrated signal on the basis of a predetermined reference signal to output the quantized signal as the form of the digital bitstream.

A sigma-delta modulator 11a receives the analog detection current of an A-phase power line, and converts and outputs the received analog detection current into a bitstream. Likewise, a sigma-delta modulator 11b and a sigma-delta modulator 11c receive the analog detection currents of B-phase and C-phase power lines, respectively, and convert and output the received analog detection currents into the bitstreams.

Similarly, a sigma-delta modulator lid receives the analog detection voltage of the A-phase power line, and converts and outputs the received analog detection voltage into the bitstream. Further, a sigma-delta modulator lie and a sigma-delta modulator 11f receive the analog detection voltages of the B-phase and C-phase power lines, respectively, and convert and output the received analog detection voltages into the bitstreams.

Subsequently, a first register 12a receives the bitstreams of the detection currents outputted from the sigma-delta modulators 11a to 11c and may store the received bitstreams in different addresses (S221). Further, a second register 12b receives the bitstreams of the sigma-delta modulators 11d to 11f and may store the received bitstreams in different addresses (S222). That is, the first register 12a stores each of the bitstreams for the plurality of detection currents (S221) and the second register 12b stores each of the bitstreams for the plurality of detection voltages (S222). Each of the first register 12a and the second register 12b receives and stores the outputs of the sigma-delta modulators in parallel through the plurality of inputs and sequentially outputs the stored data by using one output.

Subsequently, the first register 12a and the second register 12b sequentially output the bitstreams of the plurality of detection currents and the bitstreams of the plurality of detection voltages, respectively stored therein, and particularly, simultaneously output both the bitstream of the detection current and the bitstream of the detection voltage detected in the same power line, respectively (S241 and S242). The operations of the first register 12a and the second register 12b may be controlled by the register controller 14 (S23). The register controller 14 controls the first register 12a and the second register 12b to sequentially output the bitstreams of the plurality of stored detection currents and the bitstreams of the plurality of stored detection voltages, respectively. In particular, the register controller 14 controls the first register 12a and the second register 12b to simultaneously output both the bitstream of the detection current and the bitstream of the detection voltage which are detected in the same power line. Even without an additional phase error correction circuit, the above-described controlling of the register controller 14 allows for accurate calculation of watt-hours by removing a phase error between the detection current and the detection voltage which are detected in the same power line.

Subsequently, a first decimation filter 13a and a second. decimation filter 13b decimates the outputs of the first register 12a and the second register 12b, respectively to convert the decimated outputs into digital values having predetermined number of bits (S251 and S252).

The decimation filters 13a and 13b extract low-frequency components, corresponding to the original analog detection current and detection voltage before oversampling, from the digital bitstream generated by oversampling and convert the extracted low-frequency components into multi-bit digital values. The digital values for the detection current and the detection voltage outputted by the first decimation filter 13a and the second decimation filer 13b may be inputted into the power calculator 16.

The power calculator 16 may calculate power for each of the A to C-phase power lines by performing a digital calculation process by using the digital values of the detection current and the detection voltage. In FIG. 1, an example in which the power calculator 16 calculates effective power by multiplying the detection current and the detection voltage by using multipliers 161a to 161c is shown. However, although not specifically shown, the power calculator 16 may calculate various power-related parameters such as a power factor, as well as power such as effective power or ineffective power through a digital calculation process using the digital values of the detection current and the detection voltage detected in each of the A to C-phase power lines.

Meanwhile, in the exemplary embodiment of the present invention, the digital values of the plurality of detection currents and detection voltages, outputted from the first decimation filter 13a and the second decimation filter 13b, may be respectively stored in a third register 15a and a fourth register 15b according to the power lines (S261 and S262).

In this case, the register controller 14 controls the third register 15a and the fourth register 15b to distinguish the power line from which respective digital signals are sequentially inputted into the third register 15a and the fourth register 15b.

The third register 15a and the fourth register 15b may simultaneously output the digital values of the detection voltages and the detection currents detected in the plurality of power lines, and the power calculator 16 may simultaneously calculate watt-hours for the plurality of power lines by using the outputs of the third register 15a and the fourth register 15b.

Meanwhile, the electronic watt-hour meter according to the exemplary embodiment of the present invention may further include elements in order to receive additional analog information, which may be used to calculate watt-hours, and convert the received analog information into digital values. The additional information may include a current value of a neutral power line for calculating the magnitude of a leakage current, an ambient temperature value, and a power voltage VBAT of the watt-hour meter.

In order to convert the additional information into the digital values, the electronic watt-hour meter according to the exemplary embodiment of the present invention may further include a sigma-delta modulator 11g receiving analog detection current detected in the neutral power line, a sigma-delta modulator 11h receiving an analog detection temperature obtained by detecting an ambient temperature, and a sigma-delta modulator 11i receiving the analog power voltage VBAT. Further, the electronic watt-hour meter according to this exemplary embodiment may further include a register 12c storing outputs of the sigma-delta modulators 11g to 11i, a decimation filter 13c converting the bitstreams sequentially outputted from the register 12c into the digital values, and a register 15c storing the output of the decimation filter 13c and outputting the output of the decimation filter 13c again. The register 12c and the register 15c may operate according to the control of the register controller 14.

As described above, in the exemplary embodiment of the present invention, a sigma-delta modulator and a decimation filter included in a general sigma-delta analog-digital converter are separated from each other, and digital bitstreams outputted from a plurality of sigma-delta modulators are sequentially provided to a single decimation filter to generate digital values.

To enable this, the register controller 14 needs to appropriately control an input (write) and an output (read) of the first register 12a and the second register 12b.

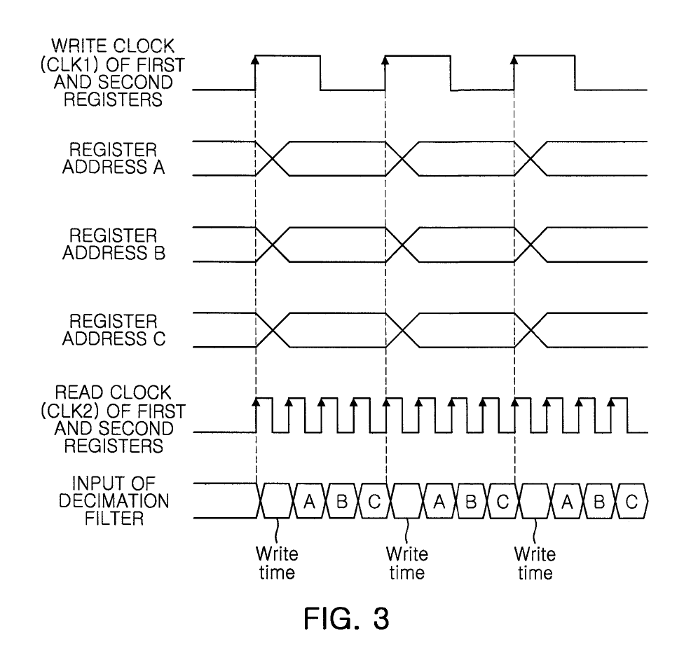

FIG. 3 is a timing diagram showing a register control clock and a register operation of an electronic watt-hour meter according to an exemplary embodiment of the present invention.

The register controller 14 may provide a write control clock CLK1 and a read control clock CLK2 to the first and second registers 12a and 12b as shown in FIG. 3. Further, in FIG. 3, in each of the first and second registers 12a and 12b, an address storing a signal detected in the A-phase power line is represented by register address A, an address storing a signal detected in the B-phase power line is represented by register address B, and an address storing a signal detected in the C-phase power line is represented by register address C.

As shown in FIG. 3, by the clock CLK1 controlling an inputting operation of the register, i.e., a writing operation, the addresses of the first and second registers 12a and 12b receive the outputs of the sigma-delta modulators 11a to 11f and perform the writing operation. Ina rising edge of the clock CLK1, the writing operation is simultaneously performed in the addresses of individual registers.

Meanwhile, the clock CLK2 controlling an outputting operation of the register, i.e., a reading operation may use a frequency four times faster than that of the clock CLK1 controlling the writing operation. In a first rising edge of the clock CLK2 controlling the reading operation, stand-by of the reading operation for the writing operation is performed in the registers 12a and 12b. Subsequently, in a second rising edge of the clock CLK2, the registers 12a and 12b may output the bitstream of the detection signal detected in the A-phase power line. Subsequently, in a third rising edge of the clock CLK2, the registers 12a and 12b may output the bitstream of the detection signal detected in the B-phase power line. Subsequently, in a fourth rising edge of the clock CLK2, the registers 12a and 12b may output the bitstream of the detection signal detected in the C-phase power line.

As described above, with regard to the clocks controlling the reading operations of the first and second registers 12a and 12b, the reading operations may be performed the same number of times as the number of the power lines detecting current or voltage during a cycle in which the writing operation is performed once. Accordingly, when the number of the power lines detecting the current or voltage is n, the frequency of the clock controlling the reading operation of each of the first and second registers 12a and 12b should be n times more than that of the clock controlling the writing operation.

Further, the operations of the third and fourth registers 15a and 15b may be performed by changing the write and read clocks of the first and second registers 12a and 12b. That is, since the clock CLK2 is the read clock of the first and second registers 12a and 12b in front ends of the decimation filters 13a and 13b, the clock CL2 is provided to the third and fourth registers 15a and 15b in rear ends of the decimation filters 13a and 13b in sequence according to the same cycle, and as a result, the digital values of the detection signals may be separately written in each of addresses of the third and fourth registers 15a and 15b according to the power lines. Furthermore, in the reading operation of each of the third and fourth registers 15a and 15b, the digital values recorded in the addresses of individual registers are simultaneously outputted according to the clock CLK1 to be provided to the power calculator 16. As a result, the power calculator 16 may calculate watt-hours of A, B, and C phase power lines at the same time.

As described above, the overall size of an electronic watt-hour meter can be reduced by reducing the number of decimation filters occupying a large amount of space and removing a phase error correction circuit for phase correction.

In general, a decimation filter may be implemented by the combination of filters having a plurality of stages. In particular, in the case in which a high signal-to-noise ratio is required, the number of stages should be further increased, and as a result, the size occupied by the decimation filter is further increased.

In exemplary embodiments of the present invention, since digital bitstreams outputted from a plurality of sigma-delta modulators may be converted into digital values by using a single decimation filter which is mutually shared, the overall size of the electronic watt-hour meter can be reduced.

Further, instead of a MUX or DEMUX, a register is used as an analog circuit. Since the register can be implemented by only one D-flip-flop for each bit, a watt-hour meter using the register can be configured to have a circuit size smaller than that using a MUX or DEMUX.

In addition, digital operations are enabled even with the reduced number of analog circuit components as compared to those in the known watt-hour meter, thereby more accurately calculating watt-hours.

As set forth above, the overall size of an electronic watt-hour meter can be reduced by reducing the number of decimation filters occupying a large amount of space and removing a phase error correction circuit for phase correction.

Further, an electronic watt-hour meter has a reduction in the number of analog circuit components and can be digitally controlled to thereby more accurately calculate watt-hours.

While the present invention has been shown and described in connection with the exemplary embodiments, it will be apparent to those skilled in the art that modifications and variations can be made without departing from the spirit and scope of the invention as defined by the appended claims.

What is claimed is:

1. An electronic watt-hour meter comprising:
a plurality of sigma-delta modulators converting a plurality of analog detection currents, acquired by detecting currents flowing through a plurality of power lines having different phases, and a plurality of analog detection voltages, acquired by detecting voltages applied to the plurality of power lines, into respective bitstreams;
a first register storing the bitstreams of the plurality of detection currents;
a second register storing the bitstreams of the plurality of detection voltages;
a register controller controlling the first register and the second register to sequentially output the bitstreams of the plurality of detection currents and the bitstreams of the plurality of detection voltages, respectively, while simultaneously outputting bitstreams of detection currents and bitstreams of detection voltages detected in the same power line;
a first decimation filter converting the bitstreams of the plurality of detection currents sequentially outputted from the first register into digital values; and
a second decimation filter converting the bitstreams of the plurality of detection voltages sequentially outputted from the second register into digital values.

2. The electronic watt-hour meter of claim 1, further comprising:
third and fourth registers storing the digital values of the plurality of detection currents outputted from the first decimation filter and the plurality of detection voltages outputted from the second decimation filter, respectively, according to each of the plurality of power lines,
wherein the register controller controls the third register and the fourth register to distinguish the power lines, through which the digital values are sequentially inputted into the third register and the fourth register, and store the digital values in different addresses.

3. The electronic watt-hour meter of claim 1, wherein the register controller provides a clock controlling a writing operation and a clock controlling a reading operation to the first register and the second register, and
a frequency of the clock controlling the reading operation is n times (n is the number of the plurality of power lines having different phases) more than that of the clock controlling the writing operation.

4. The electronic watt-hour meter of claim 1, further comprising:
a plurality of additional sigma-delta modulators receiving at least one piece of analog information including a detection leakage current acquired by detecting a current flowing through a neutral power line, a detection temperature acquired by detecting an ambient temperature, and an analog power voltage, and converting values corresponding thereto into bitstreams;
a fifth register storing the plurality of bitstreams converted by the plurality of additional sigma-delta modulators and sequentially outputting the plurality of bitstreams by a control of the register controller; and
a third decimation filter converting the bitstreams sequentially outputted from the fifth register into digital values.

5. The electronic watt-hour meter of claim 4, further comprising a sixth register storing the digital values converted by the third decimation filter according to types of the analog information.

6. A method of calculating watt-hours, the method comprising:
converting a plurality of analog detection currents, acquired by detecting currents flowing through a plurality of power lines having different phases, and a plurality of analog detection voltages, acquired by detecting voltages applied to the plurality of power lines, into respective bitstreams through sigma-delta modulation;
storing the bitstreams of the plurality of detection currents in a first register;
storing the bitstreams of the plurality of detection voltages in a second register;
sequentially outputting, by the first register and the second register, the bitstreams of the plurality of detection currents and the bitstreams of the plurality of detection voltages while simultaneously outputting bitstreams of detection currents and bitstreams of detection voltages detected in the same power line; and
converting the bitstreams of the plurality of detection currents, sequentially outputted from the first register, into digital values and converting the bitstreams of the plurality of detection voltages, sequentially outputted from the second register, into digital values.

7. The method of claim 6, further comprising storing the digital values of the plurality of detection currents in a third register according to each of the plurality of power lines and storing the digital values of the plurality of detection voltages in a fourth register according to each of the plurality of power lines,
wherein the digital values, sequentially inputted into the third register and the fourth register, are stored in different addresses by distinguishing between the power lines, in which the digital values are detected.

8. The method of claim 6, wherein the first register and the second register are operated by a clock controlling a writing operation and a clock controlling a reading operation, and
a frequency of the clock controlling the reading operation is n times (n is the number of the plurality of power lines having different phases) more than that of the clock controlling the writing operation.
